(19) United States
(12) Patent Application Publication
(10) Pub. No.: US 2019/0043908 A1
(43) Pub. Date: Feb. 7, 2019

(54) ELECTROMAGNETIC-WAVE-TRANSMITTING FILTER AND ELECTROMAGNETIC-WAVE-SENSING DEVICE

(71) Applicant: SHARP KABUSHIKI KAISHA, Sakai City (JP)

(72) Inventors: YUKIO TAMAI, Sakai City (JP); TAKASHI NAKANO, Sakai City (JP); SHINOBU YAMAZAKI, Sakai City (JP); DAISUKE HONDA, Sakai City (JP)

(21) Appl. No.: 16/035,839

(22) Filed: Jul. 16, 2018

(30) Foreign Application Priority Data
Aug. 4, 2017 (JP) 2017-151719

(51) Int. Cl. H01L 27/146; G02B 5/20; G02B 5/30

(52) U.S. Cl. CPC H01L 27/14625; G02B 5/30; G02B 5/201

(57) ABSTRACT

The disclosure has an object to restrain properties of a filter from declining in reducing the filter in size. A periodically structured filter includes a plural types of filters. At least one of the plural types of filters is structured so as to have an optical parameter or shape that changes perpendicular to the normal to the surface of that filter with a prescribed spatial regular pattern. At least one of filters of an identical type in each unit and at least one of units adjacent to that unit is adjacent.

### FIELD OF THE INVENTION

The present disclosure relates to electromagnetic-wave-transmitting filters that transmit electromagnetic waves having specific wavelengths or polarized in specific directions.

### BACKGROUND OF THE INVENTION

Light-sensing devices such as imaging devices and spectroscopes include optical filters. Japanese Unexamined Patent Application Publication, Tokukai, Nos. 2008-177191A (Publication Date: Jul. 31, 2008) and 2015-106149A (Publication Date: Jun. 8, 2015) disclose examples of such optical filters. The former Publication discloses a metal optical filter formed by a metal film with periodic openings. The latter Publication discloses an optical filter including a polarizing filter layer with a grid of wires that has a smaller period than the wavelengths of light in the region to be used.

### SUMMARY OF THE INVENTION

### Problems to be Solved by the Invention

However, for example, if the optical filter is decreased in size to match the decreasing size of pixels, the number of openings arranged in regular patterns in the optical filter also decreases, which could impair desirable inherent properties of the optical filter.

The present disclosure, in an aspect thereof, has an object to provide a filter capable of restraining inherent properties thereof from declining in reducing the filter in size.

### Solution to the Problems

To address these problems, the present disclosure, in an aspect thereof, is directed to an electromagnetic-wave-transmitting filter including an array of units each including at least two types of filters, each type of filter transmitting electromagnetic waves of a different range of wavelengths or of a different polarizing direction in a selective manner, at least one of the plural types of filters being structured so as to have an optical parameter or shape that changes perpendicular to a normal to a surface of that filter with a prescribed spatial regular pattern, and at least one of filters of an identical type in each unit and at least one of units adjacent to that unit being adjacent.

### Advantageous Effects of the Invention

The present disclosure, in an aspect thereof, results in the advantage of restraining properties of a filter from declining in reducing the filter in size.

### BRIEF DESCRIPTION OF DRAWINGS

FIG. 1 is a schematic diagram showing an example structure of a periodically structured filter in accordance with Embodiment 1.

FIG. 2 is a schematic diagram showing an example structure of an imaging device.

Portion (a) of FIG. 3 represents an example structure of a conventional periodically structured filter, and (b) of FIG. 3 represents an example structure of a periodically structured filter in accordance with Embodiment 1.

FIG. 4 represents another example structure of a periodically structured filter in accordance with Embodiment 1.

Portions (a) to (c) of FIG. 5 are schematic diagrams showing example structures of a periodically structured filter in accordance with Embodiment 2.

FIG. 6 is a schematic diagram showing an example structure of a periodically structured filter in accordance with Embodiment 3.

Portions (a) and (b) of FIG. 7 are schematic diagrams showing example structures of a periodically structured filter in accordance with Embodiment 3.

FIG. 8 is a schematic diagram showing an example structure of a periodically structured filter in accordance with Embodiment 4.

FIG. 9 is a diagram showing a specific example structure of the periodically structured filter shown in FIG. 8.

FIG. 10 illustrates a periodically structured filter in accordance with Embodiment 5. Portions (a) to (d) of FIG. 10 are diagrams showing example layouts of a plurality of openings in two adjacent filters in two adjacent units.

FIG. 11 illustrates the periodically structured filter in accordance with Embodiment 5 and is diagrams showing example layouts of a plurality of openings in the two filters in the case where the openings are formed linearly.

### DESCRIPTION OF EMBODIMENTS

### Embodiment 1

### Structure of Imaging Device

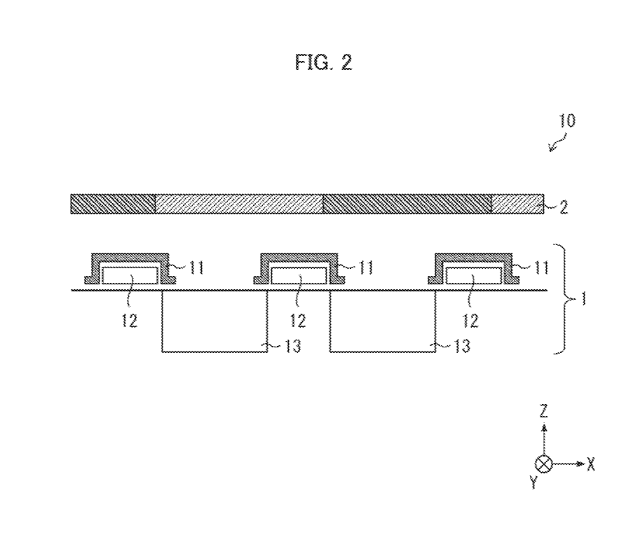

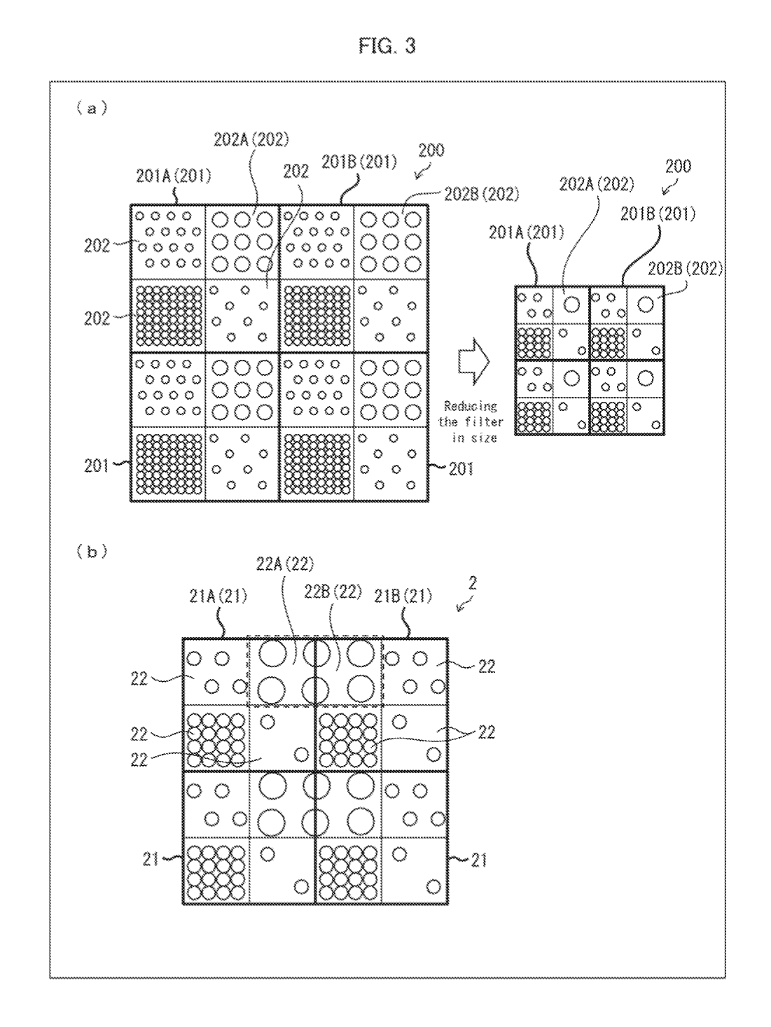

FIG. 2 is a schematic diagram showing an example structure of an imaging device 10. The imaging device 10 is mounted, for example, to a mobile information terminal. The imaging device 10 includes imaging elements 1 and a periodically structured filter 2 as shown in FIG. 2. In the imaging device 10, the periodically structured filter 2 and the imaging elements 1 are stacked in this sequence, as shown in FIG. 2, when viewed from the direction in which light strikes the imaging device 10.

Each imaging element 1 includes a plurality of conversion elements that converts the light having passed through the periodically structured filter 2 (visible, infrared, or ultraviolet light) to electric signals. The conversion elements are arranged in a one- or two-dimensional pattern. Each conversion element in the imaging element 1 forms one pixel (e.g., red, green, or blue pixel).

Still referring to FIG. 2, each imaging element 1 includes, for example, transfer lines 11 and 12 and a photodiode 13 (conversion element). The transfer lines 11 and 12 run in the X-axis direction and the Y-axis direction respectively to transfer the outputs of the photodiodes 13 to a control unit (not shown) in the imaging device 10. The photodiode 13 is a light-receiving element that receives light transmitted by the periodically structured filter 2. Each photodiode 13 forms one pixel in the imaging element 1. In other words, the photodiodes 13 as a plurality of pixels are arranged in a one- or two-dimensional pattern in the imaging element 1.

The imaging elements 1 are for sensing light as electromagnetic wave. The imaging elements 1 may be replaced by an array of conversion elements that sense and convert electromagnetic wave other than light (e.g., terahertz wave and millimeter wave) to electric signals. This alternative construction provides an electromagnetic-wave-sensing device that includes the array of conversion elements and the periodically structured filter 2 to sense electromagnetic waves. In other words, the imaging device 10 including the imaging elements 1 is an example of electromagnetic-wave-sensing devices that sense electromagnetic waves. An electromagnetic-wave-sensing device other than the imaging device 10 is, for example, a spectroscope.

The periodically structured filter 2 is an electromagnetic-wave-transmitting filter composed of plural types of filters 22 that selectively transmit light polarized in respective directions or having respective wavelengths. In the imaging device 10, the periodically structured filter 2 is an optical filter that selectively transmits light polarized in different directions or having different wavelengths. The periodically structured filter 2 is, for example, a polarizing filter or a color filter. The periodically structured filter 2 is disposed on the imaging elements 1 such that each filter 22 in the periodically structured filter 2 is located facing a different one of the imaging elements 1. This structure enables the imaging elements 1 to selectively receive light having different properties.

The periodically structured filter 2 has a size that may be specified in accordance with, for example, the size of the imaging elements 1. Alternatively, the size of the periodically structured filter 2 may be specified in accordance with the size of the parts, of the imaging elements 1, that need to be located to face the periodically structured filter 2.

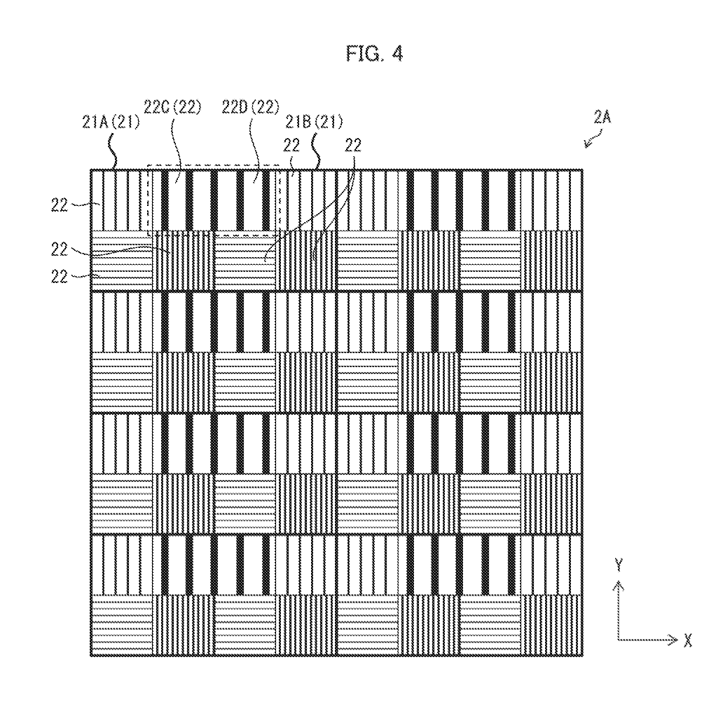

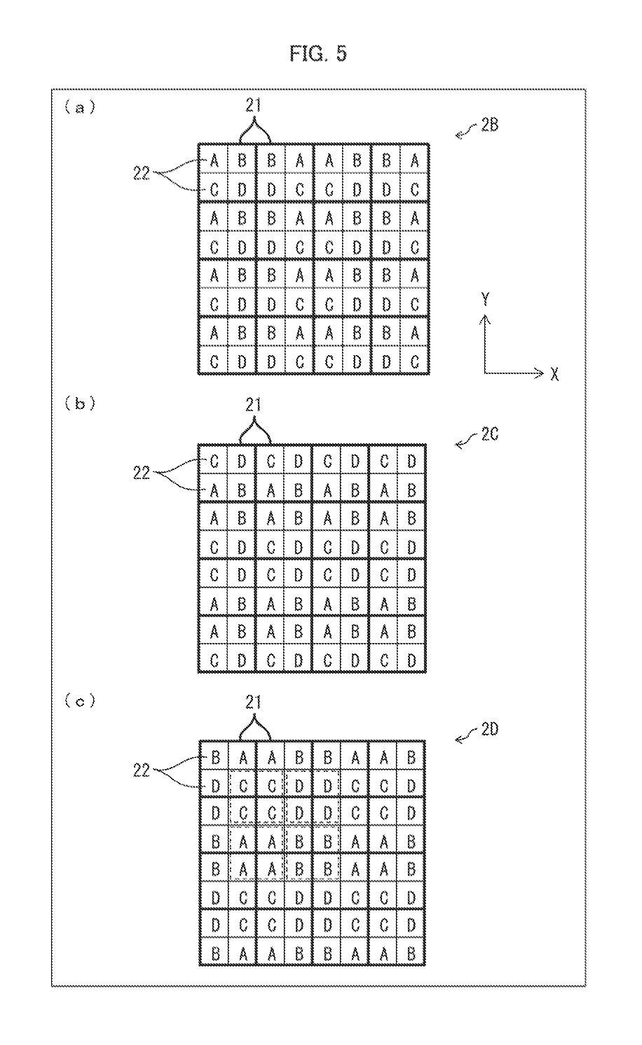

At least one of the plural types of filters 22 is structured so as to have an optical parameter (e.g., refractive index or permittivity) or shape (e.g., concavities and/or convexities) that changes perpendicular to the normal to the surface of the filter 22 with a prescribed spatial regular pattern (hereinafter, “periodicity,” “periodic,” and “periodically” all refer to this spatial regular pattern). See, for example, (b) of FIG. 3 and FIGS. 4, 6, and 9. The filter 22 may be described as having a periodic structure.

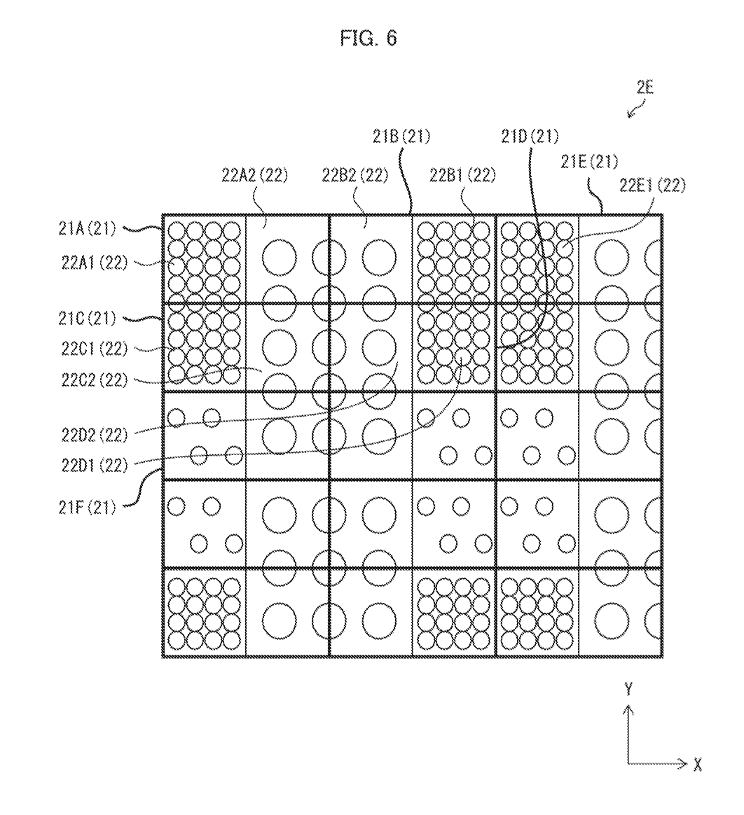

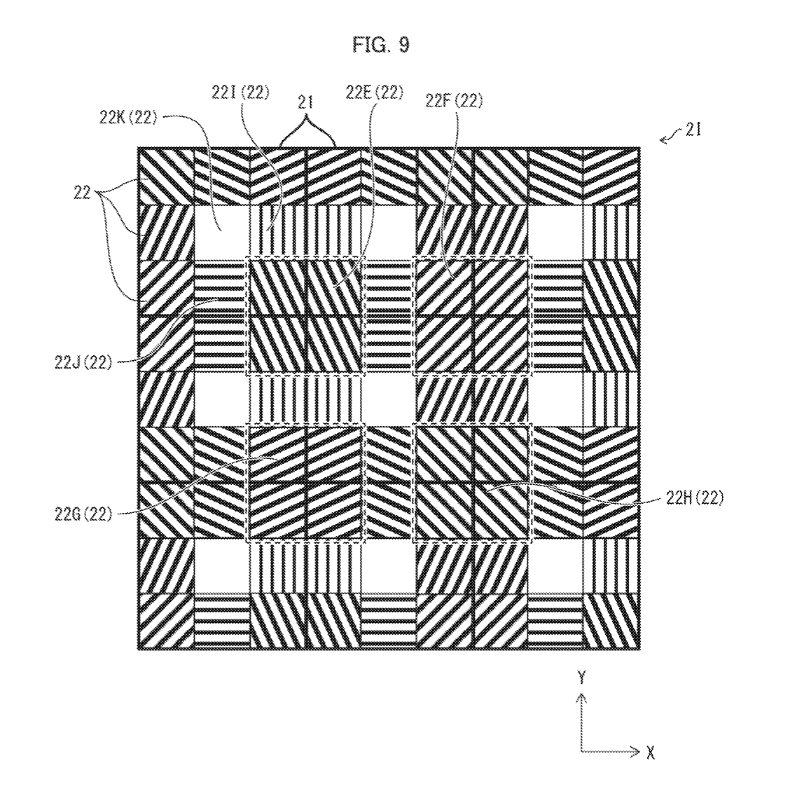

The filter 22 is composed of, for example, either periodically arranged different materials (e.g., materials with different permittivities) or photonic crystals with periodic concavities and/or convexities. The filter 22 includes, for example, a metal (e.g., aluminum, silver, gold, or copper) thin film having a plurality of openings that may or may not be filled with a dielectric. Alternatively, the filter 22 may be constructed of a stack of filters each having a plurality of openings. The openings may be, for example, circular (see, for example, (b) of FIG. 3 and FIG. 6), elliptical, rectangular, or linear (see, for example, FIGS. 4 and 9). If openings are provided, the openings are equivalents of the concavities, and the rest is equivalents of the convexities.

The plural types of filters 22 with different properties (i.e., with different wavelengths or polarizing directions) can be prepared by varying the size of the openings and/or the interval (or “pitch”) that separates adjacent openings. Alternatively, such filters 22 may be prepared by varying the refractive index of the dielectric that fills the openings. In photonic crystals, the plural types of filters 22 with different properties can be prepared by, for example, a periodic layout of materials or concavities and/or convexities, different depths of concavities and/or convexities, or different angles of concavities and/or convexities (angles of the surfaces of concavities and/or convexities with respect to the surface of the filter 22).

Alternatively, the filter 22 may include a line or lines (one-dimensional periodic pattern) of segments having an optical parameter or shape that changes periodically (e.g., openings, concavities and/or convexities, or segments with different permittivities). The filter 22 can be endowed with optical polarization selectivity as well as wavelength selectivity when the filter 22 is provided with periodically arranged lines of openings or like segments. The filter 22 can be endowed with wavelength selectivity even when the filter 22 is provided with a non-linear pattern of such segments.

One of the plural types of filters 22 may be an organic or inorganic filter (e.g., filter 22K in FIG. 9) that exhibits no periodicity in a direction perpendicular to the normal to the surface of the filter 22.

Next will be described an example structure of the electromagnetic-wave-transmitting filter by taking, as examples, periodically structured filters 2 and 2A to 2I that are made of a metal film with openings. Similar layouts may be incorporated into other types of periodically structured filters that have one of the various structures described above.

### Example Structure of Periodically Structured Filter

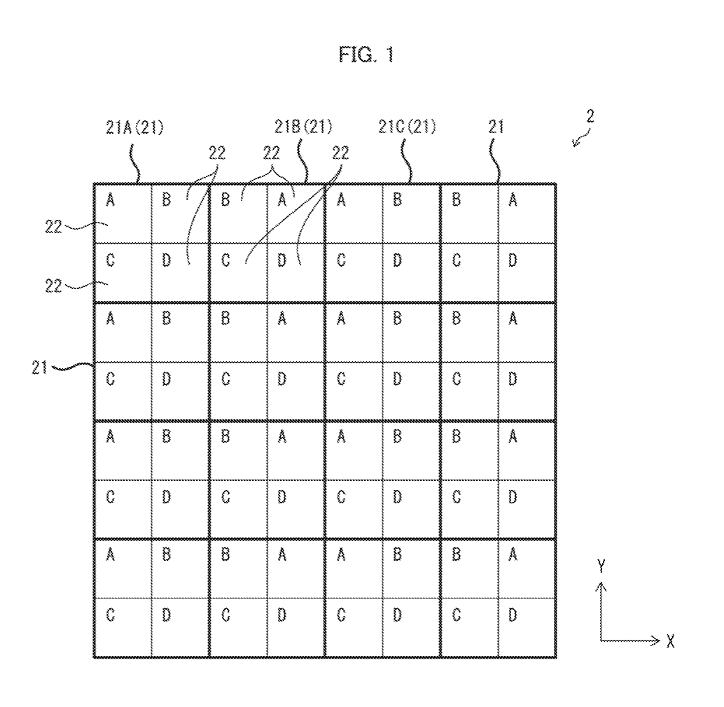

FIG. 1 is a schematic diagram showing an example structure of the periodically structured filter 2. The filters 22 have different properties (come in different types) as denoted by “A” to “D” in FIG. 1. To put it differently, the filters 22 of types “A” to “D” differ in the size of the openings and/or the interval separating adjacent openings. Note that the filters 22 in FIGS. 5, 7, and 8 have different properties as denoted similarly by alphabet letters, which will be described later in detail.

As shown in FIG. 1, the periodically structured filter 2 includes an array of units 21 each including different types (here, four types) of filters 22.

Not all the filters 22 that form each unit 21 are necessarily different from each other. Some of the filters 22 may be of the same type. Each unit 21 includes at least two different types of filters 22.

In the example shown in FIG. 1, each unit 21 includes a 2×2 array of four filters 22 each of a different type. Generally speaking, each unit 21 may include an m×n array of filters 22, where m and n are positive numbers, but are not simultaneously equal to 1.

In the periodically structured filter 2, the filters 22 are arranged such that at least one of the filters 22 in each unit 21 is adjacent to a filter 22 of the same type in at least one of the units 21 adjacent to that unit 21. In the example shown in FIG. 1, the type-B filters 22 in units 21A and 21B, which are one of pairs of units 21 that are adjacent in the X-axis direction (row direction), are adjacent to each other. In addition, the type-A filters 22 in the unit 21B and another unit 21C, which are another one of pairs of units 21 that are adjacent in the X-axis direction, are adjacent to each other.

The periodically structured filter 2 may be alternatively described as having a structure including type-A to type-D filters 22 along the periphery of each unit 21. According to this description, at least one of the filters 22 arranged along the periphery of each unit 21 is adjacent to a filter 22 of the same type located along the periphery of at least one of the units 21 adjacent to that unit 21. Alternatively, each filter 22 may be described as being located in a corner of a unit 21. According to this description, at least one of the filters 22 located in the corners of each unit 21 is adjacent to a filter 22 of the same type located in a corner of at least one of the units 21 adjacent to that unit 21.

Portion (a) of FIG. 3 represents an example structure of a conventional periodically structured filter 200, and (b) of FIG. 3 represents an example structure of the periodically structured filter 2 in accordance with the present embodiment. In (a) of FIG. 3, each unit 201 includes four types of filters 202 as in the periodically structured filter 2 shown in FIG. 1. Portion (b) of FIG. 3 shows an example in which the periodically structured filter 2 in FIG. 1 includes filters 22 each having a plurality of openings.

In the periodically structured filter 200 shown in (a) of FIG. 3, the four types of filters 202 in each unit 201 are arranged in the same manner as those in the other units 201. Therefore, no filters 202 of the same type are adjacent to each other in adjacent units 201 in the periodically structured filter 200. For example, in units 201A and 201B, which are one of pairs of adjacent units 201, filters 202A and 202B, which are one of the four pairs of filters 202 of the same type, are not adjacent to each other.

If the periodically structured filter is reduced in size, each filter can generally accommodate fewer openings. A filter has properties that are dictated by a periodic pattern of openings. If the periodically structured filter is reduced in size, the periodic pattern of openings is repeated fewer times due to the reduction in the number of openings. Therefore, each filter exhibits poorer properties (including a poorer optical filtering characteristics) in the periodically structured filter that is reduced in size than in the periodically structured filter that is not reduced in size.

In the example shown in (a) of FIG. 3, after the periodically structured filter 200 is reduced in size, for example, each of the filters 202A and 202B has a single opening, which impairs the inherent periodicity of the filters 202A and 202B and hence impairs the inherent properties of the filters 202A and 202B.

In contrast, in the periodically structured filter 2 in accordance with the present embodiment, filters 22A and 22B, which are a pair of filters 22 of the same type, are adjacent to each other in the units 21A and 21B, which are one of pairs of adjacent units 21, as indicated by a dotted-line frame in (b) of FIG. 3. The filters 22A and 22B correspond to the filters 202A and 202B in (a) of FIG. 3. The periodically structured filter 2 can be thus endowed with periodicity in the filters 22A and 22B. That can in turn restrain the properties of the filters 22A and 22B from declining over the case shown in (a) of FIG. 3.

As demonstrated here, the filters 22 of the same type that are adjacent to each other in units 21 in which the filters 22 reside (those filters 22 which are indicated by “A” or “B” in the example shown in FIG. 1) preferably have openings formed in such a manner as to exhibit periodicity, in view of suppression of the declining of the properties of the filters 22.

The periodicity of filters with larger openings or intervals is more likely to be impaired when the filters are reduced in size. In the example shown in (a) of FIG. 3, the periodicity of the filters 202A and 202B, which have the largest openings, is impaired. In contrast, in the periodically structured filter 2 in accordance with the present embodiment, the periodicity of even the filters 22A and 22B, which have the largest openings, can be preserved because the filters 22A and 22B are located adjacent to each other.

In view of these findings, those filters 22 which have larger openings or intervals and of which the properties are hence more likely to decline when the periodically structured filter 2 is reduced in size are preferably arranged adjacent to each other in adjacent units 21. Therefore, these filters 22 are preferably preferentially located on the periphery (or in the corners) of a unit 21.

In reducing the periodically structured filter 200 in size as in (a) of FIG. 3, the openings of the filters 202A and 202B could be combined to impart periodicity if the filters 202A and 202B were located adjacent to each other. Therefore, the properties of the filters 202A and 202B would be better restrained from declining if the filters 202A and 202B were located adjacent to each other.

The filters 22 of the same type that are adjacent to each other in adjacent units 21 may not have the largest openings or intervals. Filters 22 of any type may be adjacent to each other. The presence in the periodically structured filter 2 of filters 22 whose properties appreciably decline can be avoided if the filters 22 whose periodicity is more likely to be impaired than other filters 22 are preferentially located adjacent to each other in adjacent units 21.

### Variation Examples

FIG. 4 represents a periodically structured filter 2A, which is another example structure of the periodically structured filter 2. As shown in FIG. 4, in the periodically structured filter 2A, each filter 22 has linear openings. Each unit 21 includes four types of filters 22 that differ in the width and interval of the linear openings. The units 21 are arranged in the same manner as in FIG. 1. In FIG. 4, filters 22C and 22D, which have the largest intervals among the four types of filters 22, are adjacent to each other in the units 21A and 21B, which are one of pairs of adjacent units 21.

The properties of filters 22 of the same type that are adjacent to each other in adjacent units 21 can be restrained from declining when the openings are linear as in FIG. 4 just as in the case shown in (b) of FIG. 3 where the openings are circular.

### Embodiment 2

The following will describe another embodiment of the present disclosure. For convenience of description, members of the present embodiment that have the same function as members of the previous embodiment are indicated by the same reference numerals, and description thereof is omitted. This is also applicable to Embodiment 3 and all the subsequent embodiments. In addition, in Embodiment 2 and the subsequent embodiments, the description will focus solely on differences from the periodically structured filter 2 of Embodiment 1.

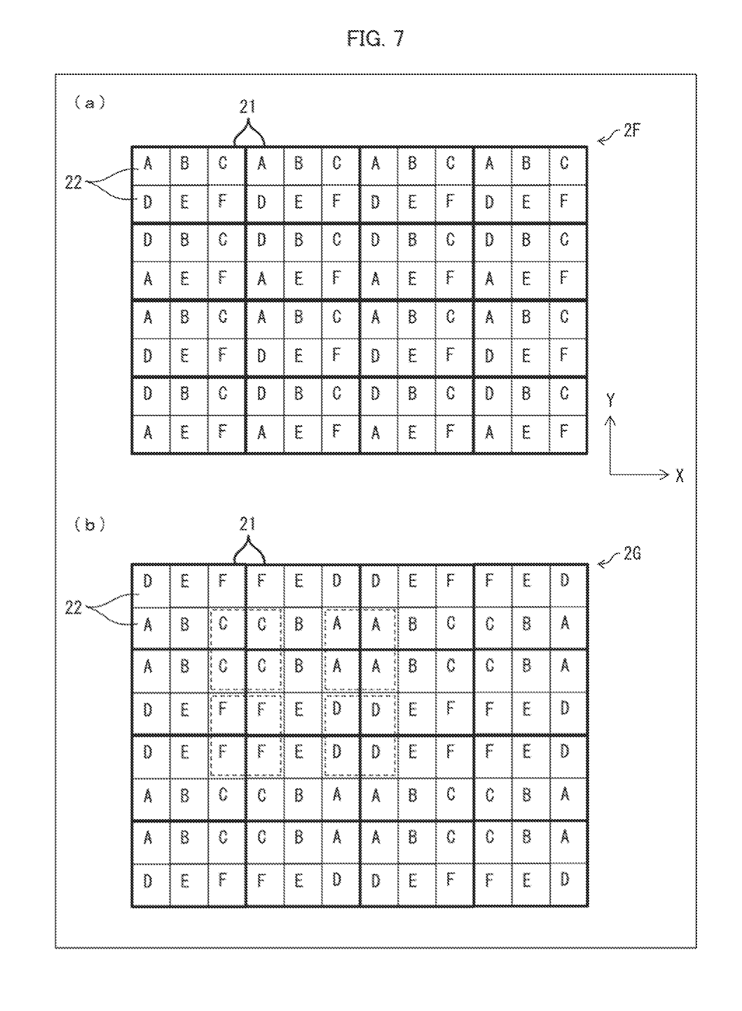

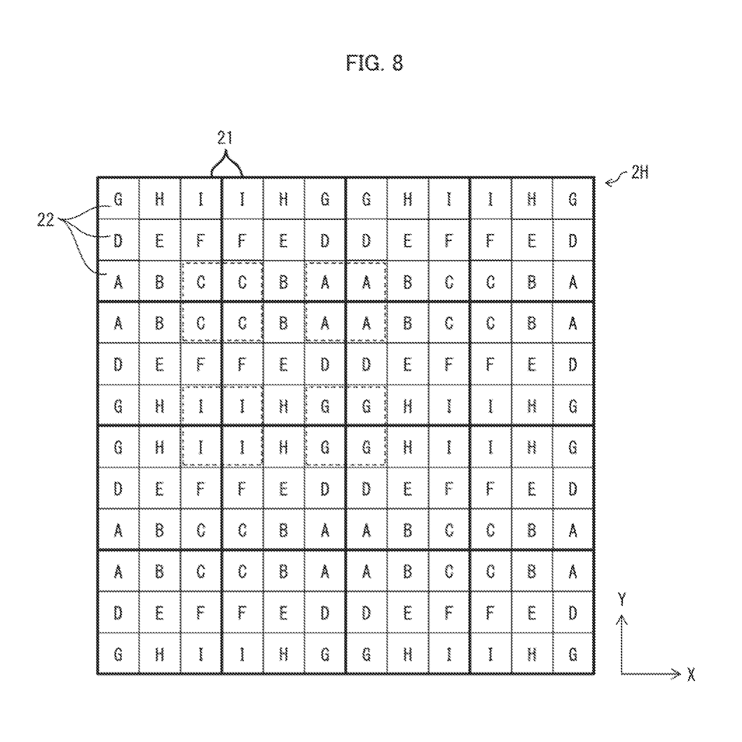

Portions (a) to (c) of FIG. 5 are diagrams respectively showing periodically structured filters 2B, 2C, and 2D in accordance with the present embodiment. Of the four types of filters 22 denoted by “A” to “D,” the filters 22 of the same type that are adjacent to each other in adjacent units 21 have openings formed in such a manner as to exhibit periodicity. The same description applies to FIGS. 7 and 8.

In (a) of FIG. 5, either two A-type filters 22 and two C-type filters 22 or two B-type filters 22 and two D-type filters 22 are adjacent to each other in each pair of units 21 that are adjacent in the X-axis direction in the periodically structured filter 2B.

In (b) of FIG. 5, either two A-type filters 22 and two B-type filters 22 or two C-type filters 22 and two D-type filters 22 are adjacent to each other in each pair of units 21 that are adjacent in the Y-axis direction (column direction) in the periodically structured filter 2C.

In (c) of FIG. 5, either two A-type filters 22 and two C-type filters 22 or two B-type filters 22 and two D-type filters 22 are adjacent to each other in each pair of units 21 that are adjacent in the X-axis direction in the periodically structured filter 2D. In addition, either two A-type filters 22 and two B-type filters 22 or two C-type filters 22 and two D-type filters 22 are adjacent to each other in each pair of units 21 that are adjacent in the Y-axis direction.

As demonstrated here, four types of filters 22 are arranged in each unit 21 in the periodically structured filters 2B to 2D such that the above-described filters 22 are adjacent to each other. Filters 22 of at least one of the four types are adjacent to each other in adjacent units 21 in the periodically structured filters 2B to 2D. These layouts can suppress declining of properties when the periodically structured filters 2B to 2D are reduced in size.

In particular, declining of properties can be suppressed progressively better if the number grows of filters 22 of the same type that are adjacent to each other in two adjacent units 21. As an example, that number is greater in the periodically structured filters 2B to 2D than in the periodically structured filter 2 (2A) of Embodiment 1. Therefore, the periodically structured filters 2B to 2D can globally better suppress the declining of their properties than can the periodically structured filter 2 (2A).

Declining of properties can also be suppressed progressively better if the area grows of the filters 22 of the same type that are adjacent to each other in adjacent units 21. In reducing a periodically structured filter in size, openings decrease by a fewer number if that area is larger. Therefore, periodicity is more likely to be preserved if the area is larger. As an example, in the periodically structured filter 2D, the four filters 22 that form a central region of four adjacent units 21 (e.g., a segment indicated by a dotted-line frame in (c) of FIG. 5) are adjacent to each other in the four units 21 and are of the same type. In the example shown in (c) of FIG. 5, each central region is formed only by filters 22 of a single type, which may be any one of A- to D-types.

More specifically, in the periodically structured filter 2D, the filter 22 located in one of the corners of any one of the units 21 is of the same type as the filters 22 located respectively in the adjacent corners of the three adjacent units 21. Therefore, the filters 22 of the same type that are adjacent to each other in the central region form a large-area cluster of such filters 22, which further restrains the properties of the filters 22 from declining. Therefore, the periodically structured filter 2D can globally better suppress the declining of their properties than can the periodically structured filters 2 and 2A to 2C.

### Embodiment 3

FIG. 6 is a diagram showing a periodically structured filter 2E in accordance with the present embodiment. Portions (a) and (b) of FIG. 7 are diagrams showing periodically structured filters 2F and 2G respectively in accordance with the present embodiment.

In the periodically structured filter 2E in FIG. 6, each unit 21 includes two types of filters 22 arranged in a 1×2 array. In the example shown in FIG. 6, each filter 22 has openings so as to exhibit periodicity. In the periodically structured filters 2F and 2G in FIG. 7, each unit 21 includes six types of filters 22 arranged in a 2×3 array.

As shown in FIG. 6, in the periodically structured filter 2E, the same type of filters 22A2 and 22B2 are adjacent to each other in units 21A and 21B, which are one of pairs of units 21 that are adjacent in the X-axis direction. The same type of filters 22B 1 and 22E 1 are adjacent to each other in the unit 21B and another unit 21E.

In the unit 21A and another unit 21C, which are one of pairs of units 21 that are adjacent in the Y-axis direction, the same type of filters 22A1 and 22C1 are adjacent to each other, and the same type of filters 22A2 and 22C2 are adjacent to each other. Likewise, in the unit 21B and another unit 21D, the same type of filters 22B2 and 22D2 are adjacent to each other, and the same type of filters 22B 1 and 22D1 are adjacent to each other.

As demonstrated here, in the periodically structured filter 2E, two types of filters 22 are located in a corner of each unit 21 such that the above-described filters 22 are adjacent to each other. Also in the periodically structured filter 2E, four filters 22 of the same type (e.g., filters 22A2, 22B2, 22C2, and 22D2) are located adjacent to each other in four adjacent units 21. These adjacent filters 22 of the same type form a large-area cluster, which readily restrains the properties of the filters 22 from declining.

The filters 22A2, 22B2, 22C2, and 22D2, all of which are of the same type, are arranged continuously in the Y-axis direction in the periodically structured filter 2E. In other words, in the periodically structured filter 2E, a pair of filters 22 of a single type that are adjacent in units 21 adjacent in the X-axis direction is adjacent in the Y-axis direction to another pair of filters 22 of the same type that are adjacent in units 21 adjacent in the X-axis direction. These adjacent filters 22 form even a larger-area cluster, which readily further restrains the properties of the filters 22 from declining. Alternatively, a pair of filters 22 of a single type that are adjacent in units 21 adjacent in the Y-axis direction may be adjacent in the X-axis direction to another pair of filters 22 of the same type that are adjacent in units 21 adjacent in the Y-axis direction.

As shown in FIG. 6, in the periodically structured filter 2E, one of the filters 22 in a unit 21F, as an example, is of a different type than one of the filters 22 in each unit 21A to 21D. As in this example, not every one of the units 21 needs to include the same types of filters 22. In other words, it is only required that there be provided adjacent filters 22 of the same type in any one of the units 21 and at least one unit 21 adjacent to that unit 21.

Referring to (a) of FIG. 7, in the periodically structured filter 2F, there are provided either two type-A filters 22 or two type-D filters 22 adjacent to each other in each pair of units 21 that are adjacent in the Y-axis direction.

Referring next to (b) of FIG. 7, in the periodically structured filter 2G, there are provided either two type-A filters 22, two type-B filters 22, and two type-C filters 22 or two type-D filters 22, two type-E filters 22, and two type-F filters 22 adjacent to each other in each pair of units 21 that are adjacent in the Y-axis direction.

Each unit 21 in the periodically structured filters 2F and 2G includes six types of filters 22 arranged such that the above-described filters 22 are adjacent to each other as detailed above. Therefore, the properties of filters 22 of a single type that are adjacent to each other in adjacent units 21 can also be restrained from declining in the periodically structured filters 2F and 2G.

In the periodically structured filter 2G, the four filters 22 that form a central region of four adjacent units 21 (e.g., a segment indicated by a dotted-line frame in (b) of FIG. 7) are adjacent to each other in the four units 21 and are of the same type. In the example shown in FIG. 7, each central region is formed only by filters 22 of a single type, which may be any one of A-, C-, D-, and F-types. The periodically structured filter 2G and the periodically structured filter 2D shown in (c) of FIG. 5 have similar structures. Therefore, the filters 22 of the same type that are adjacent to each other in the central region form a large-area cluster, which further restrains the properties of the filters 22 from declining.

The intervals in the filters 22 located in the corners of each unit 21 are preferably larger than the intervals in the filters 22 located in other positions. In the periodically structured filter 2G, as shown in (b) of FIG. 7, the intervals are preferably larger in the type-A, -C, -D, and -F filters 22 than in the type-B and -E filters 22.

The filters 22 arranged in the corners as above form large-area clusters of filters 22 in the central regions. By disposing the filters 22 that have larger intervals in the corners, their properties, which are more likely to be impaired when the filters 22 are reduced in size, can be preferentially restrained from declining.

### Embodiment 4

FIG. 8 is a diagram showing a periodically structured filter 2H in accordance with the present embodiment. In the periodically structured filter 2H in FIG. 8, each unit 21 includes nine types of filters 22 arranged in a 3×3 array.

As shown in FIG. 8, in the periodically structured filter 2H, there are provided either two type-A filters 22, two type-B filters 22, and two type-C filters 22 or two type-G filters 22, two type-H filters 22, and two type-I filters 22 adjacent to each other in each pair of units 21 that are adjacent in the Y-axis direction.

In addition, there are provided either two type-A filters 22, two type-D filters 22, and two type-G filters 22 or two type-C filters 22, two type-F filters 22, and two type-I filters 22 adjacent to each other in each pair of units 21 that are adjacent in the X-axis direction.

Besides, the four filters 22 that form a central region of four adjacent units 21 (e.g., the filters 22 located in the corners of each unit 21) are adjacent to each other in the units 21 and are of the same type. As indicated by dotted-line frames in the example shown in FIG. 8, each central region is formed only by filters 22 of a single type, which may be any one of A-, C-, G-, and I-types.

In the periodically structured filter 2H, each unit 21 includes nine types of filters 22 arranged in this manner so that the above-described filters 22, located along the periphery of the unit 21, are adjacent to each other, similarly to (c) of FIG. 5 and (b) of FIG. 7. This layout can restrain the properties of the adjacent filters 22 from declining.

It is preferable that those filters 22 with openings be located preferentially along the peripheries of the units 21 in view of declining of properties. It is also preferable that those filters 22 having larger intervals, hence having properties more likely to be impaired, be located preferentially along the peripheries of the units 21. In the example shown in FIG. 8, the type-E filters 22, which have the smallest intervals or no openings, are located at the centers of the units 21. In other words, those filters 22 with smaller intervals or with no openings may be located deep inside the units 21 (positions other than the peripheries of the units 21).

In the periodically structured filter 2H, filters 22 of the same type are located in corners that are adjacent in units 21, similarly to (c) of FIG. 5 and (b) of FIG. 7. This layout forms a large-area cluster of adjoining filters 22, which further restrains the properties of the filters 22 from declining. As is the case with other embodiments, those filters 22 having larger intervals, hence having properties more likely to be impaired, are preferably located in corners.

From the description so far, by disposing filters 22 preferentially (1) in the corners of each unit 21, (2) along the periphery except for the corners of the unit 21, and (3) inside the unit 21 except for the periphery in descending order of the magnitude of the intervals of the openings of the filters 22, the properties of the periodically structured filter 2H can be efficiently restrained from declining.

FIG. 9 is a diagram showing an example of a specific structure of the periodically structured filter 2H shown in FIG. 8. In a periodically structured filter 2I having this exemplary specific structure, each unit 21 includes eight types of filters 22 with linear openings along the periphery of the unit 21.

In this structure, similarly to the intervals, if the tilt of the linear openings of a filter 22 with respect to a side thereof becomes closer to the tilt of a diagonal of the filter 22 with respect to that side, it becomes more difficult to secure a desirable length of the line (that allows the filter to exhibit a sufficient effect) in the filter 22, and it thereby becomes more likely that the properties of the filter 22 be impaired, when the filter 22 is reduced in size. Therefore, those filters 22 in which the tilt of the openings are closer to the tilt of the diagonal are preferably located preferentially along the periphery of the unit 21 and more preferably located preferentially in the corners. In such cases, the lines can be arranged such that many of the lines run in directions in which a plurality of lines are repeated.

In the example shown in FIG. 9, those filters 22 in which the tilt of the linear openings are equal to 45° or 135° or close to either of these angles (e.g., filters 22E, 22F, 22G, and 22H) are preferentially disposed in corners of units 21. In contrast, those filters 22 in which the tilt of the openings differs relatively much from the tilt of the diagonal (e.g., filters 221 and 22J in which the lines tilt by 0° or 90°) are preferentially disposed on the peripheries of units 21 other than the corners. Those filters 22K with no openings are disposed in the center of the unit 21. If the filter 22K possesses no wavelength selectivity or optical polarization selectivity, there may be provided no filters 22K, in which case each unit 21 of the periodically structured filter 2I includes eight (not nine) types of filters 22, all of which are located along the periphery of the unit 21.

In the example shown in FIG. 9, the filters 22 in each unit 21 are disposed in positions determined on the basis of the magnitude of the tilt of the openings. Alternatively, the filters 22 may be disposed on the basis of the magnitude of the intervals.

### Embodiment 5

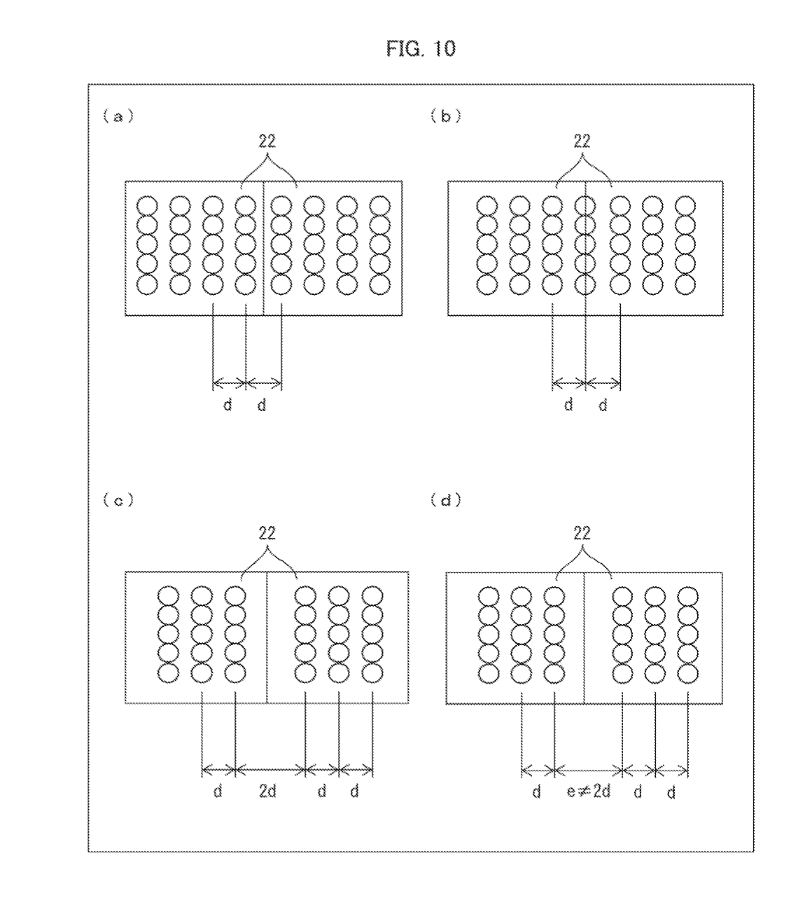

Portions (a) to (d) of FIG. 10 are diagrams showing example layouts of a plurality of openings in two adjacent filters 22 in two adjacent units 21.

In (a) of FIG. 10, each single line in the two filters 22 is formed by a plurality of openings. The lines are separated by equal intervals (each interval is approximately equal to d), and there are provided no openings on the boundary between the two filters 22. In (b) of FIG. 10, the intervals are equal, and there are provided openings on the boundary. These structures can accurately preserve the periodicity of the filters 22, thereby readily restraining the properties of the filters 22 from declining.

If a compromise may be made on this accurate preservation of the periodicity, the interval across the boundary (first interval) may differ from the intervals in other locations (inside the filters 22) (second intervals). Portion (c) of FIG. 10 shows an example where First Interval≈2d and Second Interval≈d. Portion (d) of FIG. 10 shows another example where First Interval e≠2d (and e≠d) and Second Interval≈d. These structures still preserve the periodicity to some degree, thereby being capable of restraining the properties of the filters 22 from declining. In view of the preservation of the periodicity, the structures shown in (a) and (b) of FIG. 10 are preferred.

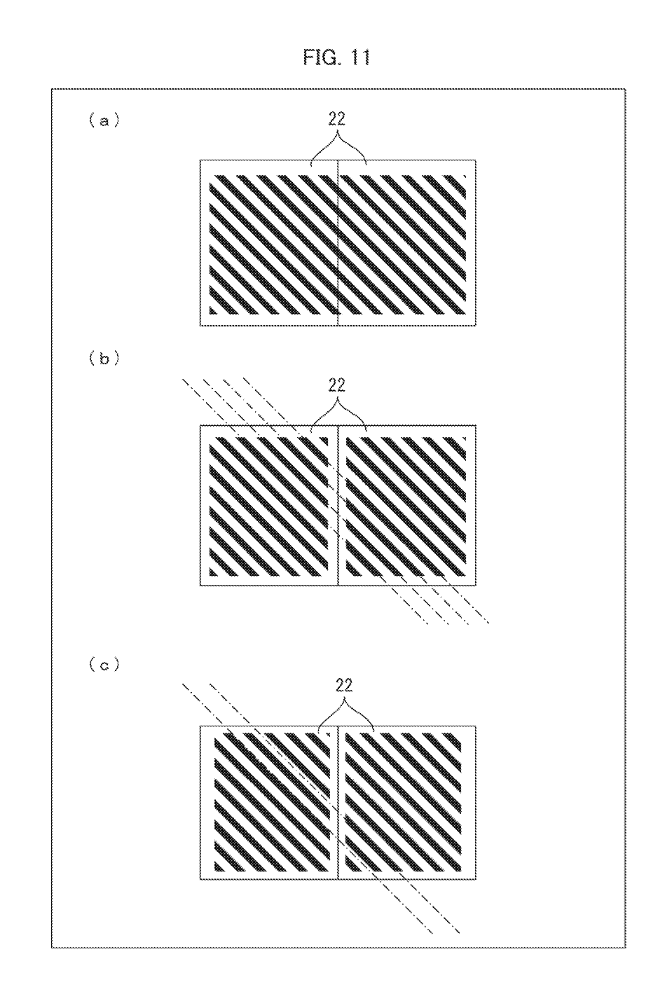

FIG. 11 is diagrams showing example layouts of a plurality of openings in the two filters 22 described above in the case where the openings are formed linearly.

In (a) of FIG. 11, the linear openings are not cut up by the boundary. This structure can accurately preserve the periodicity of the filters 22. Meanwhile, in (b) of FIG. 11, although the openings are cut up by the boundary, the openings of one of the filters 22, if extended, connect to the openings of the other filter 22. This structure can also preserve the periodicity to some accuracy. In (c) of FIG. 11, the openings are cut up by the boundary, and the openings of one of the filters 22, if extended, connect to no openings of the other filter 22. Even this structure can preserve the periodicity to some degree. In view of the preservation of the periodicity, however, the structures shown in (a) and (b) of FIG. 11 are preferred, of which the structure shown in (a) of FIG. 11 is more preferred.

### Other Matters

Each unit 21 in the periodically structured filters 2 and 2A to 2I has been described, as an example, as including an array of plural types of filters 22. These layouts of the filters 22 are mere examples, and alternatives are possible. It is only required that there be provided at least a pair of adjacent filters 22 of the same type in any one of the units 21 and at least one unit 21 adjacent to that unit 21.

Take, as an example, a periodically structured filter in which each unit 21 includes 3×3 filters 22 like the periodically structured filter 2H in FIG. 8. This periodically structured filter only requires that at least one filter 22 provided with openings and located along the periphery of any one of the units 21 be adjacent to a filter 22 of the same type in at least one unit 21 adjacent to that unit 21. Alternatively, the periodically structured filter only requires that the filter 22 provided with openings and located in a corner of any one of the units 21 be adjacent to a filter 22 of the same type located in a corner of at least one unit 21 adjacent to that unit 21.

In addition, the units 21 do not need to be arranged in a two-dimensional pattern. Alternatively, as an example, the units 21 may each include plural types of filters 22 arranged in a one-dimensional pattern and be arranged in a one-dimensional pattern.

The embodiments have described, as an example of the filter 22, a filter with a periodic pattern of openings. An alternative example of the filter 22 in accordance with the embodiments may be one that is structured so as to have an optical parameter (e.g., refractive index or permittivity) or shape (e.g., concavities and/or convexities) that periodically changes perpendicular to the normal to the surface of the filter 22 as described earlier.

In this alternative, the filter 22 preferably has, for example, at least one of the following structures (1) to (4) in view of suppression of the declining of the properties of the filter 22.

(1) The filters 22 of a single type that are adjacent in units 21 are preferably structured so as to have a periodically changing optical parameter or shape.

(2) The filter 22 structured so as to have a periodically changing optical parameter or shape is preferably located along the periphery (or in a corner) of the unit 21.

(3) The filter 22 structured so as to have an optical parameter or shape that changes periodically with a larger period is preferably preferentially located along the periphery (or in a corner) of the unit 21. For example, when segments with different permittivities or refractive indices are arranged in a sequence, those segments of any type which have equal permittivities or refractive indices have larger periods if they are separated by larger intervals. When concavities or convexities are provided in a sequence, the concavities or convexities have larger periods if they are separated by larger intervals.

(4) The filter 22 in which linear segments that impart an optical parameter or shape that changes periodically tilt with respect to a side of the filter 22 by an angle close to the angle by which the diagonal of the filter 22 tilts is preferably preferentially located along the periphery (or in a corner) of the unit 21.

The embodiments have described the imaging device 10 as including only one periodically structured filter 2 or 2A to 2I, as an example. Alternatively, the imaging device 10 may include two or more periodically structured filters 2 and 2A to 2I. In such cases, for example, (1) all these two or more periodically structured filters may be provided so as to face the imaging elements 1 (may be arranged in a two-dimensional pattern) and (2) at least some of the two or more periodically structured filters may be provided so as to face each other.

The periodically structured filters may be constructed with such specific dimensions that if, for example, the light-sensing device is to be deigned to sense light in visible to near-infrared regions, the periodic structure has a pitch of approximately from 100 nm to 1 μm to achieve desired transmission selectivity. Pixel pitches of image sensors (imaging elements) are already reduced approximately to 1 μm. If each periodically structured filter is placed across a single pixel, the periodic structure may, depending on the pitch of the periodic structure, not be repeated a sufficient number of times within the single pixel region. The present disclosure allows for a sufficient number of repetitions of the periodic structure.

The imaging device 10 may alternatively include a common color filter (e.g., Bayer array RGB filter) as well as at least one of the periodically structured filters 2 and 2A to 2I. As a further alternative, the imaging device 10 may include a common polarizing filter (e.g., polarizing filter in which the filters in every unit are arranged in the same manner) as well as at least one of the periodically structured filters 2 and 2A to 2I. In these alternatives, for example, at least one of the periodically structured filters 2 and 2A to 2I is/are disposed facing the common color filter or polarizing filter.

### General Description

The present disclosure, in aspect 1, is directed to an electromagnetic-wave-transmitting filter including an array of units each including at least two types of filters, each type of filter transmitting electromagnetic waves of a different range of wavelengths or of a different polarizing direction in a selective manner, wherein: at least one of the types of filters is structured so as to have an optical parameter (e.g., refractive index or permittivity) or shape (e.g., concavities and/or convexities) that changes perpendicular to a normal to a surface of that filter with a prescribed spatial regular pattern; and at least one of filters of an identical type in each unit and at least one of units adjacent to that unit are adjacent.

This structure can restrain filter properties from declining in reducing the electromagnetic-wave-transmitting filter in size. The structure can thereby facilitate in reducing in size a device that includes an electromagnetic-wave-transmitting filter (e.g., imaging device or spectroscope). For example, the structure allows for reduction in size of conversion elements in such devices (e.g., pixels in imaging devices). That in turn allows for reduction of chip area and chip cost. In other words, the structure helps reducing the size and manufacturing cost of the device.

The reduction of the size of the device and the accompanying reduction of the manufacturing cost thereof is of high importance in industrial applications. Therefore, the suppression of declining of filter properties in reducing the size of an electromagnetic-wave-transmitting filter is highly useful in industrial applications.

In aspect 2 of the present disclosure, the electromagnetic-wave-transmitting filter of aspect 1 may be configured such that: each unit is an m×n array of filters, where m and n are positive numbers, but are not simultaneously equal to 1; the filter structured in any of the units so as to have an optical parameter or shape that changes with a spatial regular pattern is located along a periphery of that unit; and at least one of the filters arranged along the periphery of each unit is adjacent to one of filters of the same type located along a periphery of at least one of units adjacent to that unit.

According to this structure, some of the filters are structured so as to have an optical parameter or shape that changes with a prescribed spatial regular pattern. These filters, exhibiting properties more likely to be impaired than do those filters which are not structured that way, are preferentially arranged along the peripheries of the units and adjacent to each other in adjacent units. Therefore, the properties of filters that are more likely to have their properties impaired can be preferentially restrained from declining.

In aspect 3 of the present disclosure, the electromagnetic-wave-transmitting filter of aspect 2 may be configured such that of the filters in each unit, (1) those in each of which the optical parameter or shape changes with the spatial regular pattern with a larger period or (2) those in each of which linear segments that impart an optical parameter or shape that changes with a spatial regular pattern tilt with respect to a side of that filter by an angle close to an angle by which a diagonal of the filter tilts with respect to the side of the filter are preferentially located along a periphery of the unit.

Of the filters structured to have an optical parameter or shape that changes with a prescribed spatial regular pattern, these filters (1) and (2) are more likely to have their properties further impaired when the electromagnetic-wave-transmitting filter is reduced in size. According to these structures, the filters that are more likely to have their properties impaired are arranged along the peripheries of the units and thereby have their properties preferentially restrained from declining.

In aspect 4 of the present disclosure, the electromagnetic-wave-transmitting filter of aspect 2 or 3 may be configured such that: the filter structured in any of the units so as to have an optical parameter or shape that changes with a spatial regular pattern is located in a corner of that unit; and at least one of the filters located in the corners of each unit is adjacent to one of filters of the same type located in a corner of at least one of units adjacent to that unit.

According to this structure, filters of the same type, structured so as to have an optical parameter or shape that changes with a prescribed spatial regular pattern, are arranged adjacent to each other in corners of the units. The structure can thereby restrain the properties of the filters from declining.

In addition, if each unit includes a 2×2 or larger array of filters, filters of a single type can be arranged in the adjacent corners of four adjacent units. Therefore, this layout can form a large-area cluster of filters across the corners and can thereby further restrain the properties of the filters from declining.

In aspect 5 of the present disclosure, the electromagnetic-wave-transmitting filter in any one of aspects 1 to 4 may be configured such that segments that impart an optical parameter or shape that changes with a spatial regular pattern are formed linearly.

This structure can suppress declining of properties of the filters having linearly formed segments that impart an optical parameter or shape that changes with a prescribed spatial regular pattern.

The present disclosure, in aspect 6, is directed to an electromagnetic-wave-sensing device that senses electromagnetic waves, the device including: the electromagnetic-wave-transmitting filter according to any one of aspects 1 to 5; and a plurality of conversion elements configured to convert electromagnetic waves transmitted by the electromagnetic-wave-transmitting filter to an electric signal, wherein the electromagnetic-wave-transmitting filter includes filters disposed so as to face the respective conversion elements.

This structure can suppress declining of properties of an electromagnetic-wave-transmitting filter also in reducing the conversion elements in size.

Therefore, the structure can provide a compact electromagnetic-wave-sensing device that includes an electromagnetic-wave-transmitting filter whose properties are restrained from declining.

The present disclosure, in aspect 7, is directed to an imaging device including a plurality of pixels, wherein the conversion elements in the electromagnetic-wave-sensing device according to aspect 6 form the respective pixels.

This structure can suppress declining of properties of an electromagnetic-wave-transmitting filter also in reducing the pixels in size. Therefore, the structure can provide a compact imaging device that includes an electromagnetic-wave-transmitting filter whose properties are restrained from declining.

### ADDITIONAL REMARKS

The present disclosure is not limited to the description of the embodiments above and may be altered within the scope of the claims. Embodiments based on a proper combination of technical means disclosed in different embodiments are encompassed in the technical scope of the present disclosure. Furthermore, a new technological feature may be created by combining different technological means disclosed in the embodiments.

### REFERENCE SIGNS LIST

2, 2A to 2I Periodically Structured Filter (Electromagnetic-wave-transmitting Filter)
10 Imaging Device (Electromagnetic-wave-sensing Device)
13 Photodiode (Conversion Element)
21, 21A to 21F Unit
22, 22A to 22K Filter
22A1 to 22E1, 22A2 to 22D2 Filter

What is claimed is:

1. An electromagnetic-wave-transmitting filter including an array of units each including at least two types of filters, each type of filter transmitting electromagnetic waves of a different range of wavelengths or of a different polarizing direction in a selective manner,
at least one of the plural types of filters being structured so as to have an optical parameter or shape that changes perpendicular to a normal to a surface of that filter with a prescribed spatial regular pattern, and
at least one of filters of an identical type in each unit and at least one of units adjacent to that unit being adjacent.

2. The electromagnetic-wave-transmitting filter according to claim 1, wherein:
each unit is an m×n array of filters, where m and n are positive numbers, but are not simultaneously equal to 1;
the filter structured in any of the units so as to have an optical parameter or shape that changes with a spatial regular pattern is located along a periphery of that unit; and
at least one of the plural types of the filters arranged along the periphery is identical to a type of a filter, adjacent to that filter, that is in at least one of units adjacent to a unit of interest.

3. The electromagnetic-wave-transmitting filter according to claim 2, wherein of the filters in each unit, (1) those in each of which the optical parameter or shape changes with the spatial regular pattern with a larger period or (2) those in each of which linear segments that impart an optical parameter or shape that changes with a spatial regular pattern tilt with respect to a side of that filter by an angle close to an angle by which a diagonal of the filter tilts with respect to the side of the filter are preferentially located along a periphery of the unit.

4. The electromagnetic-wave-transmitting filter according to claim 2, wherein:
the filter structured in any of the units so as to have an optical parameter or shape that changes with a spatial regular pattern is located in a corner of that unit; and
at least one of the plural types of the filters located in the corners is identical to a type of a filter located in a corner, adjacent to that corner, of at least one of units adjacent to a unit of interest.

5. The electromagnetic-wave-transmitting filter according to claim 3, wherein:
the filter structured in any of the units so as to have an optical parameter or shape that changes with a spatial regular pattern is located in a corner of that unit; and
at least one of the plural types of the filters located in the corners is identical to a type of a filter located in a corner, adjacent to that corner, of at least one of units adjacent to a unit of interest.

6. The electromagnetic-wave-transmitting filter according to claim 1, wherein segments that impart an optical parameter or shape that changes with a spatial regular pattern are formed linearly.

7. The electromagnetic-wave-transmitting filter according to claim 2, wherein segments that impart an optical parameter or shape that changes with a spatial regular pattern are formed linearly.

8. The electromagnetic-wave-transmitting filter according to claim 3, wherein segments that impart an optical parameter or shape that changes with a spatial regular pattern are formed linearly.

9. The electromagnetic-wave-transmitting filter according to claim 4, wherein segments that impart an optical parameter or shape that changes with a spatial regular pattern are formed linearly.

10. The electromagnetic-wave-transmitting filter according to claim 5, wherein segments that impart an optical parameter or shape that changes with a spatial regular pattern are formed linearly.

11. An electromagnetic-wave-sensing device that senses electromagnetic waves, comprising:
the electromagnetic-wave-transmitting filter according to claim 1; and
a plurality of conversion elements configured to convert electromagnetic waves transmitted by the electromagnetic-wave-transmitting filter to an electric signal,
wherein the electromagnetic-wave-transmitting filter includes filters disposed so as to face the respective conversion elements.

12. An electromagnetic-wave-sensing device that senses electromagnetic waves, comprising:
the electromagnetic-wave-transmitting filter according to claim 2; and
a plurality of conversion elements configured to convert electromagnetic waves transmitted by the electromagnetic-wave-transmitting filter to an electric signal,
wherein the electromagnetic-wave-transmitting filter includes filters disposed so as to face the respective conversion elements.

13. An electromagnetic-wave-sensing device that senses electromagnetic waves, comprising:
the electromagnetic-wave-transmitting filter according to claim 3; and
a plurality of conversion elements configured to convert electromagnetic waves transmitted by the electromagnetic-wave-transmitting filter to an electric signal,
wherein the electromagnetic-wave-transmitting filter includes filters disposed so as to face the respective conversion elements.

14. An electromagnetic-wave-sensing device that senses electromagnetic waves, comprising:
the electromagnetic-wave-transmitting filter according to claim 4; and
a plurality of conversion elements configured to convert electromagnetic waves transmitted by the electromagnetic-wave-transmitting filter to an electric signal,
wherein the electromagnetic-wave-transmitting filter includes filters disposed so as to face the respective conversion elements.

15. An electromagnetic-wave-sensing device that senses electromagnetic waves, comprising:
the electromagnetic-wave-transmitting filter according to claim 5; and
a plurality of conversion elements configured to convert electromagnetic waves transmitted by the electromagnetic-wave-transmitting filter to an electric signal,
wherein the electromagnetic-wave-transmitting filter includes filters disposed so as to face the respective conversion elements.

16. An electromagnetic-wave-sensing device that senses electromagnetic waves, comprising:
the electromagnetic-wave-transmitting filter according to claim 6; and
a plurality of conversion elements configured to convert electromagnetic waves transmitted by the electromagnetic-wave-transmitting filter to an electric signal,
wherein the electromagnetic-wave-transmitting filter includes filters disposed so as to face the respective conversion elements.

17. An electromagnetic-wave-sensing device that senses electromagnetic waves, comprising:
the electromagnetic-wave-transmitting filter according to claim 7; and
a plurality of conversion elements configured to convert electromagnetic waves transmitted by the electromagnetic-wave-transmitting filter to an electric signal,
wherein the electromagnetic-wave-transmitting filter includes filters disposed so as to face the respective conversion elements.

18. An electromagnetic-wave-sensing device that senses electromagnetic waves, comprising:
the electromagnetic-wave-transmitting filter according to claim 8; and
a plurality of conversion elements configured to convert electromagnetic waves transmitted by the electromagnetic-wave-transmitting filter to an electric signal,
wherein the electromagnetic-wave-transmitting filter includes filters disposed so as to face the respective conversion elements.

19. An electromagnetic-wave-sensing device that senses electromagnetic waves, comprising:
the electromagnetic-wave-transmitting filter according to claim 9; and
a plurality of conversion elements configured to convert electromagnetic waves transmitted by the electromagnetic-wave-transmitting filter to an electric signal,
wherein the electromagnetic-wave-transmitting filter includes filters disposed so as to face the respective conversion elements.

20. An electromagnetic-wave-sensing device that senses electromagnetic waves, comprising:
the electromagnetic-wave-transmitting filter according to claim 10; and
a plurality of conversion elements configured to convert electromagnetic waves transmitted by the electromagnetic-wave-transmitting filter to an electric signal,
wherein the electromagnetic-wave-transmitting filter includes filters disposed so as to face the respective conversion elements.
